(19) United States
(12) Patent Application Publication
(10) Pub. No.: US 2008/0129357 A1
(43) Pub. Date: Jun. 5, 2008

(54) Adaptive Integrated Circuit Clock Skew Correction

(76) Inventors: James D. Chlipala, Emmaus, PA (US); Scott A. Segan, Allentown, PA (US)

Correspondence Address: Ryan, Mason & Lewis, LLP, 90 Forest Avenue, Locust Valley, NY, 11560, US

(21) Appl. No.: 11/565,067

(22) Filed: Nov. 30, 2006

(51) Int. Cl. H03L 7/00

(52) U.S. Cl. 327/161

(57) ABSTRACT

Apparatus for correcting clock skew in a circuit including at least one sequential circuit element and a clock generator operatively coupled to the sequential circuit element includes at least one programmable delay element connected in series with a data input and/or a clock input of the sequential circuit element. The programmable delay element has a delay associated therewith which is selectively controllable as a function of a control signal. The apparatus further includes at least one processor connected in a feedback configuration with the sequential circuit element. The processor is operative to receive a clock signal generated by the clock generator and an output signal of the sequential circuit element and to generate the control signal as a function of the clock signal and the output signal. The processor is further operative to control a timing of a data signal supplied to the data input of the sequential circuit element.

### FIELD OF THE INVENTION

The present invention relates generally to electronic circuits, and more particularly relates to correction of clock skew in an integrated circuit (IC).

### BACKGROUND OF THE INVENTION

The arrival of clock signals at various circuit nodes in a synchronous circuit should be precisely coordinated to ensure accurate transfer of data and control information in the circuit. Clock skew is a phenomenon in synchronous circuits in which the clock signal, generally sent from a common clock circuit, arrives at different circuit nodes at different times. This is typically due to three primary causes. The first is a material flaw, which causes a signal to travel faster or slower than anticipated. The second is distance: if the signal has to travel the entire length of a circuit, it will likely (depending upon the size of the circuit) arrive at different parts of the circuit at different times. The third is the number of non-sequential (combinational) circuits in the signal path: the propagation delay through circuits such as NAND and NOR gates adds to the overall propagation delay.

If large enough, clock skew can cause errors to occur in the circuit. Suppose, for example, that a given logic path travels through combinational logic from a source flip-flop to a destination flip-flop. If the destination flip-flop receives a clock transition, often referred to as a “tick,” later than the source flip-flop, and if the logic path delay is short enough, then the data signal might arrive at the destination flip-flop before the clock transition, invalidating the previous data waiting there to be clocked through. This is often referred to as a “hold violation,” since the data is not held long enough at the destination flip-flop to achieve a valid output result. Similarly, if the destination flip-flop receives the clock tick earlier than the source flip-flop, then the data signal has that much less time to reach the destination flip-flop before the next clock tick. If the data fails to reach the destination flip-flop before the next clock tick, a “setup violation” occurs, since the new data was not set up and stable prior to the arrival of the next clock tick.

Clock skew is generally affected by one or more characteristics, including, for example, clock speed, clock driver strength, length of clock-carrying conductors, capacitance load on clock-carrying conductors, IC processing, power supply voltage level, temperature, noise, on-chip variation (OCV), number of combinational circuits, etc. The task of correcting clock skew is made more difficult by the interaction of these and other characteristics.

There are various known clock skew correction approaches. In one known skew correction technique, a “deskew” phase-locked loop (PLL) or delay-locked loop (DLL) is employed to align the respective phases of the clock inputs at two or more components in the IC. This approach is described, for example, in the paper S. Tam, et al., “Clock Generation and Distribution for the First IA-64 Microprocessor,” IEEE J Solid-State Circuits, Vol. 35, No. 11, November 2000, pp 1545-1552, which is incorporated by reference herein. Unfortunately, however, this approach suffers from area, power and complexity penalties, among other disadvantages. Another technique for reducing clock skew in the IC is to tune the clock speed. This approach is described, for example, in the paper T. Kehl, “Hardware Self-Tuning and Circuit Performance Monitoring,” In Proc. IEEE International Conference on Computer Design: VLSI in Computers and Processors, 1993, pp. 188-192, which is incorporated by reference herein. Disadvantages of this approach include a significant performance reduction due, at least in part, to slower clock speeds.

Accordingly, there exists a need for clock skew correction techniques which do not suffer from one or more of the above-noted problems exhibited by conventional clock skew correction methodologies.

### SUMMARY OF THE INVENTION

The present invention meets the above-noted need by providing, in an illustrative embodiment thereof, techniques for adaptively correcting clock skew in an IC. The clock skew correction techniques of the invention can be performed after installation of the IC in a customer system in response to actual conditions affecting circuit performance at the time of skew correction.

In accordance with one aspect of the invention, apparatus for correcting clock skew in a circuit including at least one sequential circuit element and a clock generator operatively coupled to the sequential circuit element includes at least one programmable delay element having an input adapted for receiving a data signal supplied to the circuit and/or a clock signal generated by the clock generator, and having an output coupled to a data input and/or a clock input of the first sequential circuit element. The first programmable delay element has a first delay associated therewith which is selectively controllable as a function of a first control signal. The apparatus further includes at least one processor connected in a feedback configuration with the first sequential circuit element. The processor is operative to receive the clock signal and an output signal of the first sequential circuit element and to generate the first control signal as a function of the clock signal and at least one measured timing parameter of the circuit. The processor is further operative to control a timing of the data signal supplied to the circuit.

The apparatus may further include a second sequential circuit element having an output coupled to the data input of the first sequential circuit element and having an input adapted for receiving the data signal, and a second programmable delay element having an input adapted for receiving the data signal and/or the clock signal generated. The second programmable delay element has an output coupled to a data input and/or a clock input of the second sequential circuit element. The second programmable delay element has a second delay associated therewith which is selectively controllable as a function of a second control signal.

In accordance with another aspect of the invention, a method is provided for correcting clock skew in a circuit including at least a first sequential circuit element, a clock generator operatively coupled to the first sequential circuit element and operative to generate a clock signal, at least a first programmable delay element connected in series with at least one of a data input and a clock input of the first sequential circuit element, the first programmable delay element having a first delay associated therewith, and at least one processor connected in a feedback configuration with the at least first sequential circuit element. The method includes the steps of: (i) measuring an arrival of the clock signal at the clock input of the first sequential circuit element relative to minimum setup and hold time parameters corresponding to the first sequential circuit element; (ii) increasing the first delay value when the clock signal arrives prior to the minimum setup time parameter corresponding to the first sequential circuit element; (iii) decreasing the first delay value when the clock signal arrives later than the minimum hold time parameter corresponding to the first sequential circuit element; and (iv) repeating steps (i) through (iii) until at least one of all delay values of the first programmable delay element have been selected and the arrival of the clock signal at the clock input of the first sequential circuit element satisfies the minimum setup and hold time parameters corresponding to the first sequential circuit element.

These and other features and advantages of the present invention will become apparent from the following detailed description of illustrative embodiments thereof, which is to be read in connection with the accompanying drawings.

### BRIEF DESCRIPTION OF THE DRAWINGS

FIG. 1 is an exemplary circuit diagram illustrating clocked propagation of data through signal paths in an IC.

FIG. 2 is an exemplary circuit diagram illustrating one method for correcting clock skew using fixed delay blocks.

FIG. 3 is a block diagram depicting an exemplary circuit that includes adaptive IC clock skew correction, in accordance with an embodiment of the invention.

FIG. 4 is a logic timing diagram depicting exemplary timing signals relating to the circuit shown in FIG. 3, in accordance with an aspect of the invention.

FIG. 5 is a logic timing diagram depicting exemplary timing signals relating to the circuit shown in FIG. 3, in accordance with an aspect of the invention.

FIG. 6 is a logic timing diagram depicting exemplary timing signals relating to the circuit shown in FIG. 3, in accordance with an aspect of the invention.

FIG. 7 is an illustrative logic flow diagram depicting the exemplary clock skew correction methodology shown in FIG. 6, in accordance with an aspect of the invention.

FIG. 8 is a block diagram depicting an exemplary circuit providing adaptive clock skew correction, in accordance with an embodiment of the invention.

FIG. 9 is a block diagram depicting an exemplary circuit providing adaptive clock skew correction, in accordance with another embodiment of the invention.

### DETAILED DESCRIPTION OF THE INVENTION

The present invention will be described herein in the context of illustrative clock skew correction architectures. It should be understood, however, that the present invention is not limited to these or any particular clock skew correction circuit arrangements. Rather, the invention is more generally suitable for use in any circuit application in which it is desirable to provide improved performance, at least in terms of avoiding clocking-related problems such as violation of setup and hold times. In this manner, techniques of the present invention provide enhanced skew correction performance over conventional skew correction methodologies.

FIG. 1 is an exemplary circuit 100 illustrating clocked propagation of data through signal paths in an IC. As apparent from the figure, circuit 100 includes a clock generator 102 operative to generate a common clock signal which is sent to multiple points in the IC via corresponding signal paths. Each signal path, 104, 106 and 108, has a certain delay value, D1, D2 and D3, respectively, associated therewith. Each delay value Dn is primarily a function of a clock or data path proceeding through combinatorial cells and/or over wires. The clock signal is sent through signal path 104 to a clock input of a first flip-flop (FF1) 110. Concurrently, the clock signal is sent through signal path 108 to a clock input of a second flip-flop (FF2) 112. An output (Q) of FF1 is sent through signal path 106 to a data (D) input of FF2.

Circuit 100 functions to latch a particular data bit in FF1 on a clock edge, and to latch this same data bit in FF2 on the next clock edge. By way of illustration only, assume that the input to FF1 is always correctly latched. If delays D1, D2 and D3 interact in such a way as to violate the setup or hold time specifications for FF2, there will be a high likelihood that data transmission errors will occur. For example, if delay D3 is so small and/or the sum of delays D1 and D2 is so large that the clock edge arrives at FF2 before the data input of FF2 has satisfied the setup time, a timing error will occur. Similarly, a timing error will occur if delay D3 is so large and/or the sum of delays D1 and D2 are so small that the data input of FF2 does not satisfy the hold time requirement of FF2.

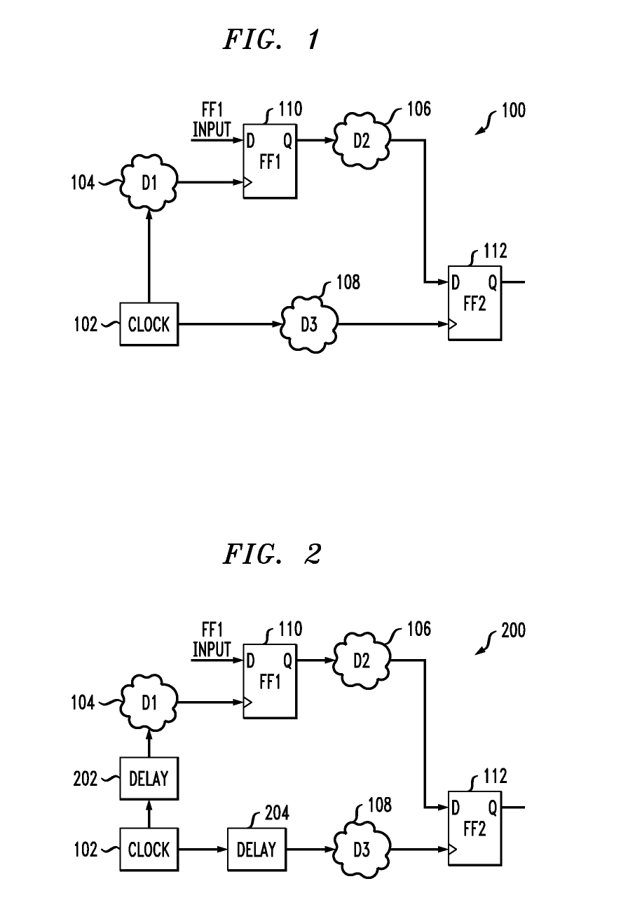

FIG. 2 is an exemplary circuit 200 illustrating clocked propagation of data through signal paths in an IC. As apparent from the figure, circuit 200 is essentially the same as circuit 100 shown in FIG. 1, except for the inclusion of two programmable delay blocks for performing clock skew correction. Specifically, circuit 200 includes a first delay block 202 connected in series with signal path 104, between the clock generator 102 and the clock input of the first flip-flop 110. Circuit 200 further includes a second delay block 204 connected in series with signal path 108, between the clock generator 102 and the clock input of the second flip-flop 112. Each of the delay blocks 202, 204 has a fixed delay value associated therewith that is preprogrammed into the delay block at the circuit design stage, prior to IC fabrication. The delay values selected for the delay blocks 202, 204 may be based, for example, on simulation results or on other circuit analysis techniques and are preferably adapted to correct a nominal clock skew between the clock input of FF1 and FF2. One disadvantage of this clock skew correction approach, however, is that it provides essentially no means to easily and/or accurately compensate for variations in clock skew caused by, among other factors, OCV, on-chip temperature gradients (OCTG), process variations across the chip, chip aging, etc.

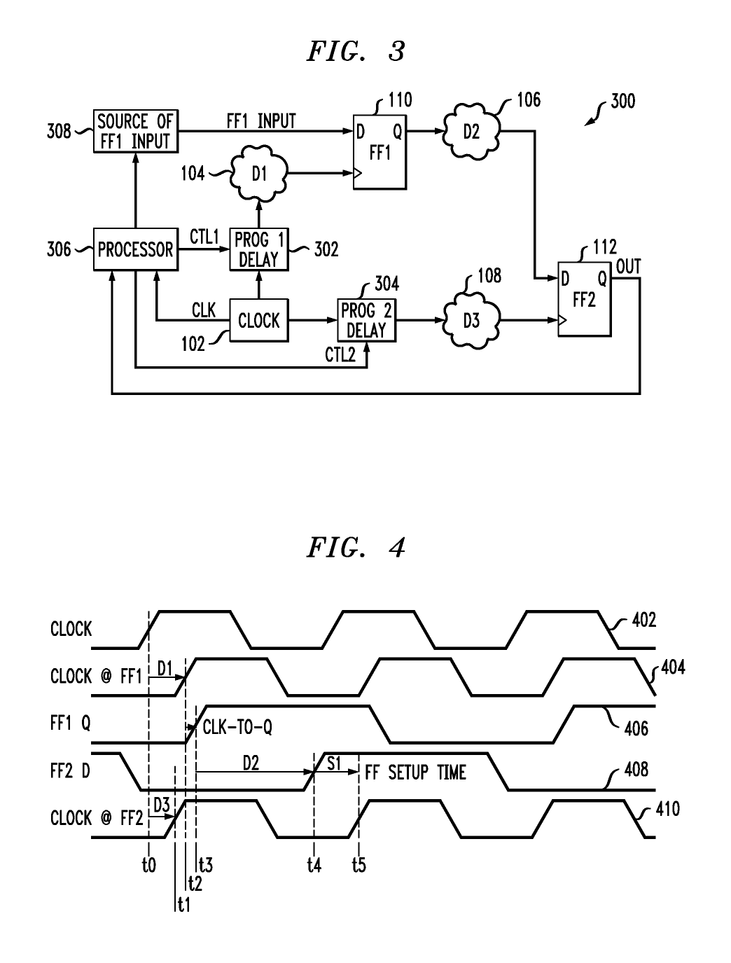

FIG. 3 is a block diagram depicting an exemplary circuit 300 providing adaptive clock skew correction, in accordance with an illustrative embodiment of the invention. It is to be understood that the invention is not limited to the particular circuit arrangement shown, and that numerous other circuit configurations in which techniques of the invention may be implemented are similarly contemplated. Circuit 300 preferably includes a clock generator 102 operative to generate a common clock signal, or other timing signal, which is sent to multiple points in the circuit via corresponding signal paths. Each signal path, 104, 106 and 108, has a certain delay value, D1, D2 and D3, respectively, associated therewith. Each delay value Dn is primarily a function of a clock or data path traversing through one or more combinatorial logic cells (not shown) and/or over wires, each component in a given signal path adding to the overall delay Dn of the path. The clock signal is sent through signal path 104 to a clock input of a first flip-flop (FF1) 110, or other sequential circuit element. The clock signal is also substantially concurrently sent through signal path 108 to a clock input of a second flip-flop (FF2) 112, or other sequential circuit element. The term “sequential circuit element” as used herein is intended to include a flip-flop, memory cell, latch circuit, or any other type of circuit or circuit element capable of capturing data. An output (Q) of FF1 is sent through signal path 106 to a data input (D) of FF2.

It is to be understood that while two sequential circuit elements (e.g., FF1 and FF2) are shown, the invention is not limited to this particular number, and that less than two (e.g., one) sequential circuit elements or more than two (e.g., three) sequential circuit elements may be employed.

An objective of the illustrative clock skew correction technique shown in FIG. 3 is to adaptively adjust clock and data arrival timing at the clock and data inputs, respectively, of FF1 and/or FF2 so as to essentially eliminate setup and/or hold time violations in the circuit. To accomplish this, circuit 300 preferably comprises one or more programmable delay elements in at least one of the signal paths. Specifically, circuit 300 includes a first programmable delay line 302 having a first delay, Prog 1 Delay, associated therewith, connected in series in signal path 104 (e.g., between clock generator 102 and the clock input of FF1). Circuit 300 further includes a second programmable delay line 304 having a second delay, Prog 2 Delay, associated therewith, connected in series in signal path 108 (e.g., between the clock generator and the clock input of FF2). Utilizing programmable delay lines offers a user the ability to control the amount of delay in a given signal path after fabrication and packaging of the device or after installation of the device in a desired application rather than using factory-trimmed, fixed-delay intervals.

Each of the programmable delay lines 302, 304 are operative to generate a delay that is selectively controllable as a function of a control signal supplied thereto. The delay associated with first programmable delay line 302 is preferably a function of a first control signal, CTL1, supplied thereto, and the delay associated with second programmable delay line 304 is preferably a function of a second control signal, CTL2, supplied thereto. It is to be understood that the present invention is not limited to any particular number of programmable delay lines. If only one programmable delay line is employed, it is preferably connected in series with a signal path having the shortest delay associated therewith in order to provide ample delay adjustment opportunity.

One or both of programmable delay lines 302, 304 may be controlled by a digital word supplied thereto. The number of bits in the digital control word is preferably matched to a resolution of the programmable delay line, so that a digital control word having an increasing number of bits is able to support a programmable delay line having an increasingly finer control resolution or greater delay range. The resolution of the programmable delay line generally refers to the number of different delay values (e.g., steps) which may be selected. Thus, for example, an 8-bit programmable delay line offers 256 different delay values which can be selected. The step size between adjacent delay values need not be linear, but may be nonlinear (e.g., logarithmic, binary, etc.). Moreover, adjacent delay value steps in the programmable delay lines need not be monotonic.

Using this circuit arrangement, the respective clock inputs to FF1 and FF2 can be selectively delayed to thereby prevent or significantly reduce setup and/or hold time violations. Moreover, the clock skew correction techniques of the invention are adaptive in that the amount of delay generated by programmable delay lines 302 and 304 can be automatically adjusted during operation of the circuit (e.g., “on the fly”) as a function of measured timing characteristics of the circuit. For example, a digital control word used to select the delay value of a given programmable delay line may be stored in a register. When it is desired to change this delay value, the register may be overwritten with a new digital control word. This adaptive clock skew correction methodology beneficially enables the circuit to easily and accurately compensate for variations in clock skew caused by, among other factors, OCV, on-chip temperature gradients, process variations across the chip, chip aging, etc., that a fixed delay approach cannot easily address.

Circuit 300 preferably includes at least one processor 306, or alternative control circuitry (e.g., state machine), operative to measure certain timing parameters of the circuit, or other characteristics which may be used to derive circuit timing information, and to generate control signals CTL1 and CTL2 as a function of the measured timing parameters. It is to be appreciated that the term “processor” as used herein is intended to include any processing device, such as, for example, one that includes a central processing unit (CPU) and/or other processing circuitry (e.g., digital signal processor (DSP), microprocessor, advanced RISC machine (ARM) processor, etc.). Additionally, it is to be understood that the term “processor” may refer to more than one processing device, and that various elements associated with a processing device may be shared by other processing devices.

In illustrative circuit 300, processor 306 is preferably configured to receive, as inputs, the clock signal, CLK, from clock generator 102 and an output signal, OUT, generated at an output (Q) of FF2. Processor 306 is also preferably operative to control an input source 308 supplying the data input to FF1. Circuit 300 may be configured, for example, to enter a calibration state or mode, wherein processor 306 is operative to control at least one of the input source 308 to FF1, the delay associated with programmable delay line 302, and the delay associated with programmable delay line 304 as a function of the clock signal CLK and/or the output signal OUT generated by FF2. The calibration state may be entered at periodic intervals during operation of the circuit 300. Likewise, one or more delay parameters of the circuit 300 may be controlled “on the fly” during normal circuit operation. In this manner, one or both of the respective clock signals fed to the inputs of FF1 and FF2 can be delayed as desired so as to essentially eliminate setup and/or hold time violations. It may be desirable to run through a given calibration cycle at a very slow clock speed (e.g., substantially slower than during normal operation of the circuit) to ensure that the processor and/or other circuitry functions correctly. The clock speed could then be increased, such as, for example, in increments, until the target speed is reached or until a system failure occurs. This technique applies to both clock spines and clock trees.

By way of example only and without loss of generality, consider FIG. 4 which is a logic timing diagram depicting exemplary timing signals relating to the circuit 300 shown in FIG. 3. Here, it is assumed that the programmable delay lines 302, 304 are configured to have a delay equal to zero. In reality, each of the programmable delay lines 302, 304 will have some non-zero delay associated therewith. With reference to FIG. 4, at time t0, the clock signal (represented by trace 402) generated by clock generator 102 goes to a logic high state. At time t1, the clock input to FF2 (represented by trace 410) goes to a logic high state after a delay D3 attributable to signal path 108. At time t2, the clock input to FF1 (represented by trace 404) goes to a logic high state after a delay D1 attributable to signal path 104. Here, it is assumed that the data input to FF1 is a logic high level, and therefore at time t3, the output of FF1 (represented by trace 406) goes to a logic high state after a certain propagation delay through FF1 (Clk-to-Q). At time t4, the output signal from FF1 arrives at the data input to FF2 (represented by trace 408) after a delay D2 attributable to signal path 106. At time t5, the start of the next clock cycle arrives at the clock input to FF2. As apparent from the figure, time t5 coincides with a setup time, S1, of FF2. The difference in time between the arrival of the data input to FF2 at time t4 and the arrival of the start of the next clock cycle at time t5, namely, t5-t4, should be equal to or greater than a specified minimum setup time of FF2 or else a setup time violation will occur.

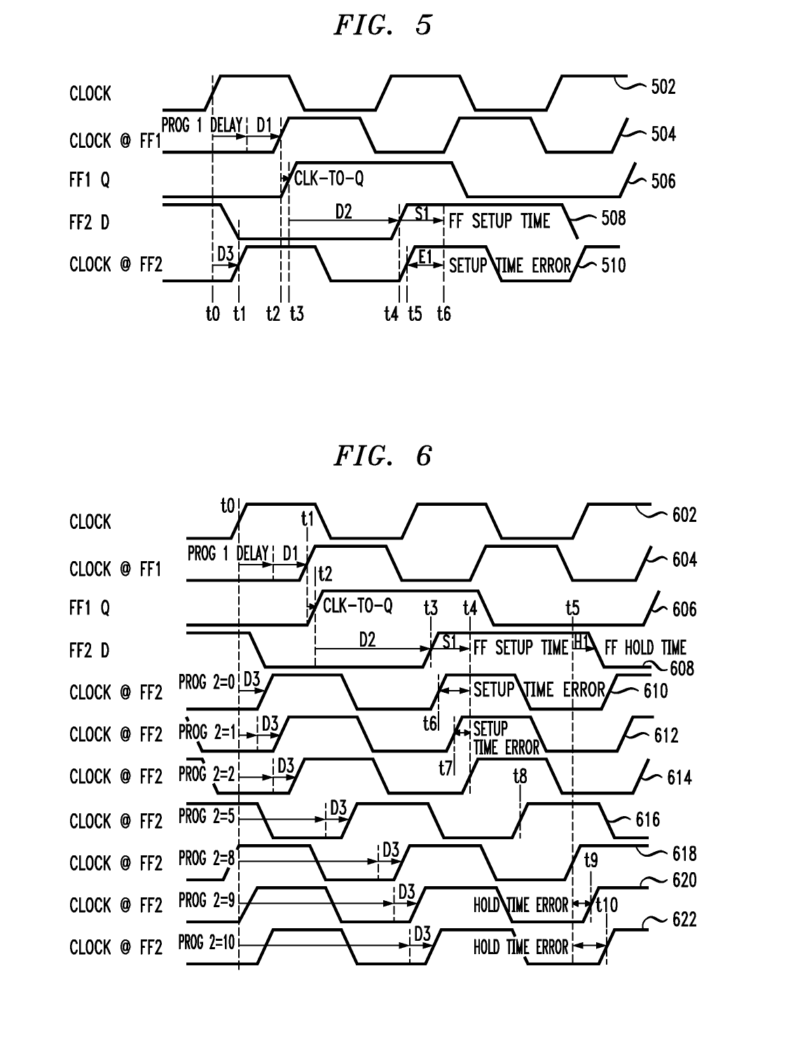

FIG. 5 is a logic timing diagram depicting exemplary timing signals relating to an illustrative methodology for correcting clock skew in the circuit 300 shown in FIG. 3, in accordance with an aspect of the invention. Here, it is assumed that programmable delay line 304 has a delay (Prog 2 Delay) equal to zero and programmable delay line 302 has a delay (Prog 1 Delay) selected to correct clock skew associated with FF1. With reference to FIG. 5, at time t0, the clock signal (represented by trace 502) generated by clock generator 102 goes to a logic high state. At time t1, the clock input to FF2 (represented by trace 510) goes to a logic high state after a delay D3 attributable to signal path 108. At time t2, the clock input to FF1 (represented by trace 504) goes to a logic high state after a delay equal to the sum of the delay D1 attributable to signal path 104 and a skew correction delay selected for programmable delay 302, namely, Prog 1 Delay. The value of Prog 1 Delay is preferably selected so as to satisfy a minimum setup time requirement of FF1. As previously stated, the minimum setup time may be defined as the minimum amount of time required between the arrival of the data signal at the data input of the flip-flop and the arrival of the clock signal at the clock input of the flip-flop.

The data input to FF1 is assumed to be a logic high level initially, and therefore at time t3, the output of FF1 (represented by trace 506) goes to a logic high state after a certain propagation delay through FF1 (Clk-to-Q). At time t4, the output signal from FF1 arrives at the data input to FF2 (represented by trace 508) after a delay D2 attributable to signal path 106. At time t5, the start of the next clock cycle arrives at the clock input to FF2. Time t6 indicates a minimum setup time S1 corresponding to FF2.

As apparent from the figure, the next clock cycle arrives prior to the minimum setup time of FF2, and thus a setup time violation exists. The difference between time t6 and time t5, namely, t6-t5, may be defined as a setup time error, E1. The clock skew associated with FF2 can be corrected by selecting an appropriate delay value Prog 2 Delay for programmable delay line 304. The delay associated with programmable delay line 304 is preferably selected to be equal to or greater than the setup time error E1. However, if this delay is made too large, a hold time violation can occur.

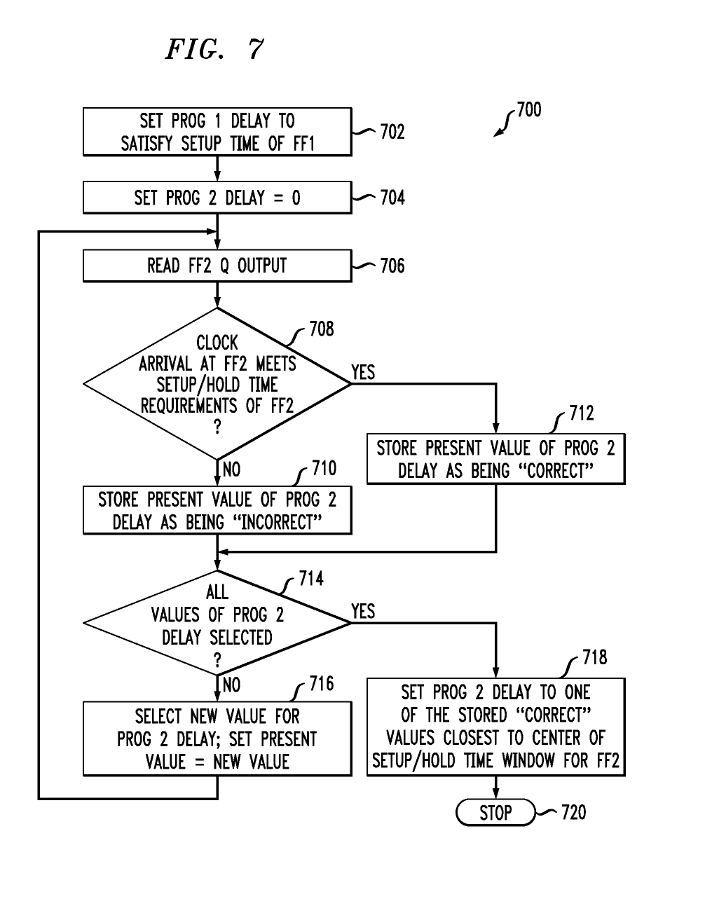

An illustrative clock skew correction methodology, in accordance with another aspect of the invention, will now be described in conjunction with FIGS. 6 and 7. FIG. 6 is a logic timing diagram depicting exemplary timing signals relating to the illustrative clock skew correction methodology. FIG. 7 is an illustrative logic flow diagram 700 depicting the exemplary clock skew correction methodology shown in FIG. 6. As previously explained, processor 306 shown in FIG. 3 is preferably operative to control the data input to FF1 and to select the delay values Prog 1 Delay and Prog 2 Delay associated with programmable delay lines 302 and 304, respectively, as a function of the clock signal CLK and the output signal OUT from FF2. In this illustrative methodology, processor 306 provides a data pattern to the data input of FF1 which alternates from logic high to logic low every clock cycle, although the present invention is not limited to any particular input data pattern for FF1.

By way of example only, it is assumed that processor 306 first sets the delay value Prog 1 Delay of programmable delay line 302 in order to correct the clock skew of FF1 (Step 702 in FIG. 7). As previously stated above in connection with FIG. 5, Prog 1 Delay is selected so as to satisfy a prescribed minimum setup time requirement of FF1. Once this delay value has been selected, it preferably remains set throughout the clock skew correction process of FF2. With reference to FIG. 6, at time to, the clock signal (represented by trace 602) generated by clock generator 102 goes to a logic high state. At time t1, the clock input to FF1 (represented by trace 604) goes to a logic high state after a delay equal to the sum of the skew correction delay selected for programmable delay 302, namely, Prog 1 Delay, and the delay D1 attributable to signal path 104. The data input to FF1 is assumed to be a logic high level initially, and therefore at time t2, the output of FF1 (represented by trace 606) goes to a logic high state after a certain propagation delay through FF1 (Clk-to-Q).

At time t3, the output signal from FF1 arrives at the data input to FF2 (represented by trace 608) after a delay D2 attributable to signal path 106. Time t4 indicates a minimum setup time, S1, corresponding to FF2. Time t5 indicates a minimum hold time, H1, corresponding to FF2. Thus, during the clock skew correction process for FF2, the processor 306 is preferably operative to select a value for Prog 2 Delay such that the arrival of the clock signal at the clock input to FF2 is within the window defined by times t4 and t5 (e.g., greater than or equal to time t4 and less than or equal to time t5).

Traces 610 through 622 represent the clock input to FF2 for several selected values of Prog 2 Delay. Specifically, trace 610 represents the clock input to FF2 when Prog 2 Delay is set to 0, trace 612 represents the clock input to FF2 when Prog 2 Delay is set to 1, trace 614 represents the clock input to FF2 when Prog 2 Delay is set to 2, trace 616 represents the clock input to FF2 when Prog 2 Delay is set to 5, trace 618 represents the clock input to FF2 when Prog 2 Delay is set to 8, trace 620 represents the clock input to FF2 when Prog 2 Delay is set to 9, and trace 622 represents the clock input to FF2 when Prog 2 Delay is set to 10. These values will correlate to some time delay generated by the programmable delay line 304. As apparent from the figure, the delay values need not be sequential or linear, but may correspond to essentially any time delay amounts.

When Prog 2 Delay is set to 0, as in trace 610, the arrival of the clock signal at FF2 occurs at time t6 which is prior to time t4. Therefore, a setup time violation will occur. The processor preferably reads the output of FF2 and records the present value of Prog 2 Delay as being an “incorrect” value due to the setup time error. The processor then selects a new value for Prog 2 Delay, such as, for example, by incrementing the delay amount of the programmable delay line 304. When Prog 2 Delay is set to 1, as in trace 612, the arrival of the clock signal at FF2 occurs at time t7 which is prior to time t4. Again, a setup time violation will occur. The processor preferably reads the output of FF2 and records the present value of Prog 2 Delay as being an “incorrect” value due to the setup time error. The processor then selects a new value for Prog 2 Delay and the clock skew correction process of FF2 continues.

When Prog 2 Delay is set to 2, as in trace 614, the arrival of the clock signal at FF2 will be substantially coincident with time t4, and thus the setup time requirement of FF2 will be satisfied. The processor reads the output of FF2 and preferably records the present value of Prog 2 Delay as being a “correct” value due to the lack of a setup time violation. The processor then selects a new value for Prog 2 Delay. When Prog 2 Delay is set to 5, as in trace 616, the arrival of the clock signal at FF2 will be substantially centered in the window defined by times t4 and t5. This setting may be more optimal since it can better compensate for variations in clock skew caused by, among other factors, OCV, on-chip temperature gradients, process variations across the chip, chip aging, etc. When Prog 2 Delay is set to 8, as in trace 618, the arrival of the clock signal at FF2 will be substantially coincident with time t5, the upper boundary of the window, and thus the hold time requirement of FF2 will be satisfied.

If the delay value of programmable delay line 304 in FIG. 3 is set too high, a hold time violation can occur. This is the case in traces 620 and 622. When Prog 2 Delay is set to 9, as in trace 620, the arrival of the clock signal at FF2 occurs at time t9 which is after time t5. Therefore, a hold time violation will occur. The processor preferably reads the output of FF2 and records the present value of Prog 2 Delay as being an “incorrect” value due to the hold time error. The processor then selects a new value for Prog 2 Delay. When Prog 2 Delay is set to 10, as in trace 622, the arrival of the clock signal at FF2 occurs at time t10 which is after time t5. Again, a hold time violation will occur. The processor preferably reads the output of FF2 and records the present value of Prog 2 Delay as being an “incorrect” value due to the hold time error. The processor then selects a new value for Prog 2 Delay and the clock skew correction process of FF2 continues in this manner until all delay values have been selected for Prog 2 Delay.

With reference to FIG. 7, after setting the value of Prog 1 Delay, the value of Prog 2 Delay is preferably initially set to zero (e.g., minimum delay) in step 704. The output of FF2 is then read in step 706. In step 708, the arrival of the clock signal at the clock input to FF2 is measured relative to the setup and hold time window defined by times t4 and t5 in FIG. 6 to determine whether or not the arrival of the clock signal satisfies the setup and hold time requirements of FF2. If the arrival of the clock signal at FF2 falls outside this setup and hold time window (e.g., less than t4 or greater then t5), the present value of Prog 2 Delay is stored as “incorrect” in step 710. This case is indicated by traces 610 and 612 shown in FIG. 6, wherein arrival of the clock signal at FF2 occurs at times t6 and t7, respectively, which are prior in time to t4 and therefore violate the minimum setup time requirement of FF2. This case is similarly indicated by traces 620 and 622 in FIG. 6, wherein the clock signal arrives at FF2 at times t9 and t10, respectively, which are later than time t5 and therefore violate the hold time requirement of FF2. If arrival of the clock signal at FF2 falls within the setup and hold time window (t5-t4), as indicated by traces 614, 616 and 618 shown in FIG. 6, the present value of Prog 2 Delay is stored as “correct” in step 712. In either case, program control proceeds to step 714, where the process 700 checks to see whether or not all values of Prog 2 Delay have been selected. It is to be understood that the above methodology is merely illustrative, and that other techniques may be similarly employed to accomplish the dynamic skew correction objectives of the present invention.

In step 714, if it is determined that not all values of Prog 2 Delay have been selected, a new value for Prog 2 Delay is chosen in step 716 by incrementing the delay in programmable delay line 304 (see FIG. 3). The present value is set equal to this new delay value and the process proceeds to step 706, where the output of FF2 is again read. If it has been determined in step 714 that all delay values have been selected, Prog 2 Delay is preferably set to one of the stored “correct” values closest to a center of the setup and hold time window in step 718. As apparent from FIG. 6, trace 616 indicates a Prog 2 Delay value for which the arrival of the clock signal at FF2 is substantially centered within the window defined by times t4 and t5. By selecting a delay value which makes the arrival of the clock signal at FF2 closest to the center of the setup and hold time window, the circuit can compensate for slight variations in timing resulting from, among other factors, OCV, on-chip temperature gradients, process variations across the chip, chip aging, etc., as previously stated.

After selecting an appropriate value for programmable delay line 304, the clock skew correction methodology stops at step 720. As previously stated, this clock skew correction methodology can be performed, for example, as part of a periodic calibration procedure, upon power up, or whenever an error is detected in the output signal OUT of the circuit.

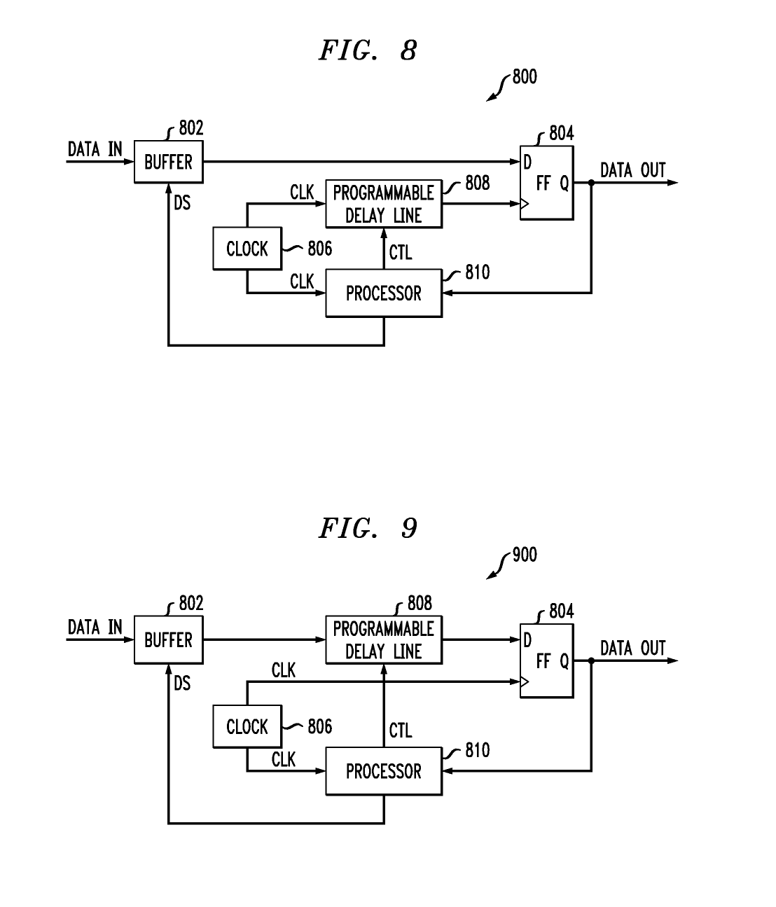

FIG. 8 is a block diagram depicting an exemplary circuit 800 providing adaptive clock skew correction, in accordance with another embodiment of the invention. In this simplified embodiment, which may be used, for example, in a data deskewing application, only one sequential circuit element and one programmable delay line are employed. Specifically, circuit 800 includes a buffer 802 connected to a data (D) input of a flip-flop (FF) 804 and adapted to receive input data (e.g., from a data source). Buffer 802 is preferably adapted for selectively providing one of the input data and a signal indicative of the input signal (e.g., a logical complement of the input data) to an output of the buffer. A clock generator 806 is connected to a clock input of the FF 804 through a series-connected programmable delay line 808 and is operative to generate a clock signal CLK. Programmable delay line 808 has a delay associated therewith that is selectively controllable as a function of a control signal, CTL, supplied thereto.

Circuit 800 further comprises a processor 810 operative to receive the clock signal CLK and an output signal, DATA OUT, generated at an output (Q) of FF 804, and to generate the control signal CTL. Processor 810 is also operative to generate a data strobe signal, DS, which may be used to control at least a timing of the data input presented to FF 804. Thus, processor 810 is connected in a feedback configuration around FF 804. Processor 810 may function to adaptively correct clock skew in circuit 800 in a manner consistent with that described above in conjunction with FIG. 3. In other embodiments of the invention, the programmable delay line may be connected in series with the data input of the FF, as shown in FIG. 9, or programmable delay lines may be connected in series with both the data and clock inputs of the FF.

FIG. 9 is a block diagram depicting an exemplary circuit 900 providing adaptive clock skew correction, in accordance with an embodiment of the invention. Circuit 900 is essentially the same as circuit 800 shown in FIG. 8, except that programmable delay line 808 is connected in series with the data input of FF 804, rather than the clock input of the FF. Specifically, circuit 900 includes a buffer 802 connected to an input of programmable delay line 808 and adapted to receive input data (e.g., from a data source). An output of the programmable delay line 808 is coupled to the data input of FF 804. Processor 810 preferably generates an appropriate control signal CTL so as to adaptively correct skew problems relating to arrival of the input data signal DATA IN at the data input of FF 804 relative to arrival of the clock signal CLK at the clock input of the FF.

At least a portion of the methodologies of the present invention may be implemented in an integrated circuit. In forming integrated circuits, die are typically fabricated in a repeated pattern on a surface of a semiconductor wafer. Each of the die includes a device described herein, and may include other structures or circuits. Individual die are cut or diced from the wafer, then packaged as integrated circuits. One skilled in the art would know how to dice wafers and package die to produce integrated circuits. Integrated circuits so manufactured are considered part of this invention.

Although illustrative embodiments of the present invention have been described herein with reference to the accompanying drawings, it is to be understood that the invention is not limited to those precise embodiments, and that various other changes and modifications may be made therein by one skilled in the art without departing from the scope of the appended claims.

What is claimed is:

1. Apparatus for correcting clock skew in a circuit including at least a first sequential circuit element and a clock generator operatively coupled to the first sequential circuit element, the apparatus comprising:
at least a first programmable delay element having an input adapted for receiving at least one of a data signal supplied to the circuit and a clock signal generated by the clock generator, and having an output coupled to at least one of a data input and a clock input of the first sequential circuit element, the first programmable delay element having a first delay associated therewith which is selectively controllable as a function of a first control signal; and
at least one processor connected in a feedback configuration with the at least first sequential circuit element, the processor being operative to receive the clock signal and an output signal of the first sequential circuit element and to generate the first control signal as a function of the clock signal and at least one measured timing parameter of the circuit, the processor being further operative to control a timing of the data signal supplied to the circuit.

2. The apparatus of claim 1, further comprising a second programmable delay element having an input adapted for receiving the data signal and having an output coupled to the data input of the first sequential circuit element, the input of the first programmable delay element being adapted to receive the clock signal and the output of the first programmable delay element being coupled to the clock input of the first sequential circuit element, the second programmable delay element having a second delay associated therewith which is selectively controllable as a function of a second control signal.

3. The apparatus of claim 1, further comprising:
a second sequential circuit element having an output coupled to the data input of the first sequential circuit element and having an input adapted for receiving the data signal; and
a second programmable delay element having an input adapted for receiving at least one of the data signal supplied to the circuit and the clock signal generated by the clock generator, and having an output coupled to at least one of a data input and a clock input of the second sequential circuit element, the second programmable delay element having a second delay associated therewith which is selectively controllable as a function of a second control signal.

4. The apparatus of claim 3, wherein the at least one processor is further operative to generate the second control signal as a function of the clock signal and the at least one measured timing parameter of the circuit.

5. The apparatus of claim 3, wherein the input of the first programmable delay element is adapted to receive the clock signal, the output of the first programmable delay element is coupled to the cock input of the first sequential circuit element, the input of the second programmable delay element is adapted to receive the clock signal, and the output of the second programmable delay element is coupled to the clock input of the second sequential circuit element.

6. The apparatus of claim 3, wherein the at least one processor is operative: (i) to set a value of the second delay so as to satisfy a prescribed minimum setup time parameter of the second sequential circuit element; (ii) to set the first delay associated with the first programmable delay element to a minimum delay value; (iii) to measure an arrival of the clock signal at the clock input of the first sequential circuit element relative to minimum setup and hold time parameters corresponding to the first sequential circuit element; (iv) when the arrival of the clock signal at the clock input of the first sequential circuit element does not satisfy the minimum setup and hold time parameters corresponding to the first sequential circuit element, to increment the first delay value; and (v) to repeat steps (iii) and (iv) until at least one of all delay values of the first programmable delay element have been selected and the arrival of the clock signal at the clock input of the first sequential circuit element satisfies the minimum setup and hold time parameters corresponding to the first sequential circuit element.

7. The apparatus of claim 6, wherein the at least one processor is operative to select a value of the first delay for which the arrival of the clock signal at the clock input of the first sequential circuit element is substantially centered in a window defined by the minimum setup and hold time parameters corresponding to the first sequential circuit element.

8. The apparatus of claim 1, wherein the at least one measured timing parameter comprises the output signal of the first sequential circuit element.

9. The apparatus of claim 1, further comprising at least one buffer including an input for receiving the data signal and an output connected to the data input of the first sequential circuit element, the buffer being operative to selectively provide one of the data signal and a signal indicative of the data signal to the output of the buffer as a function of a second control signal.

10. The apparatus of claim 9, wherein the at least one processor is further operative to generate the second control signal.

11. The apparatus of claim 1, further comprising at least one buffer including an input for receiving the data signal and an output connected to the data input of the first sequential circuit element, the buffer being adapted to selectively provide one of the data signal and a signal indicative of the data signal to the output of the buffer, the at least one processor being operative to generate a strobe signal supplied to the buffer for selectively controlling at least a timing of the data signal presented to the first sequential circuit element.

12. The apparatus of claim 1, wherein the first programmable delay element is configured such that the first delay associated therewith is selectively adjustable in non-monotonic steps.

13. The apparatus of claim 1, wherein the first programmable delay element is configured such that the first delay associated therewith is selectively adjustable in linear steps.

14. The apparatus of claim 1, wherein the first programmable delay element is configured such that the first delay associated therewith is selectively adjustable in nonlinear steps.

15. The apparatus of claim 1, wherein the at least one processor is operative to control an arrival of the data signal at the data input of the first sequential circuit element relative to an arrival of the clock signal at the clock input of the first sequential circuit element so as to satisfy a prescribed minimum setup time parameter corresponding to the first sequential circuit element.

16. The apparatus of claim 1, wherein the at least one processor is operative to control a value of the first delay so as to adaptively correct clock skew in the circuit during normal operation of the circuit.

17. An integrated circuit, comprising at least one apparatus as set forth in claim 1.

18. In a circuit including at least a first sequential circuit element, a clock generator operatively coupled to the first sequential circuit element and operative to generate a clock signal, at least a first programmable delay element connected in series with at least one of a data input and a clock input of the first sequential circuit element, the first programmable delay element having a first delay associated therewith, and at least one processor coupled in a feedback configuration with the first sequential circuit element, a method for correcting clock skew comprising the steps of:
(i) measuring an arrival of the clock signal at the clock input of the first sequential circuit element relative to minimum setup and hold time parameters corresponding to the first sequential circuit element;
(ii) increasing the first delay value when the clock signal arrives prior to the minimum setup time parameter corresponding to the first sequential circuit element;
(iii) decreasing the first delay value when the clock signal arrives later than the minimum hold time parameter corresponding to the first sequential circuit element; and
(iv) repeating steps (i) through (iii) until at least one of all delay values of the first programmable delay element have been selected and the arrival of the clock signal at the clock input of the first sequential circuit element satisfies the minimum setup and hold time parameters corresponding to the first sequential circuit element.

19. The method of claim 18, wherein the circuit further includes a second sequential circuit element having an output coupled to the data input of the first sequential circuit element and having an input adapted for receiving the data signal, and a second programmable delay element coupled to the second sequential circuit element and having a second delay associated therewith, the method further comprising the steps of:
setting a value of the second delay so as to satisfy a prescribed minimum setup time parameter of the second sequential circuit element;
setting the first delay associated with the first programmable delay element to a minimum delay value;
when the arrival of the clock signal at the clock input of the first sequential circuit element does not satisfy the minimum setup and hold time parameters corresponding to the first sequential circuit element, incrementing the first delay value; and
repeating the steps of measuring the arrival of the clock signal and incrementing the first delay value until at least one of all delay values of the first programmable delay element have been selected and the arrival of the clock signal at the clock input of the first sequential circuit element satisfies the minimum setup and hold time parameters corresponding to the first sequential circuit element.

20. A system for correcting clock skew, comprising:
at least a first sequential circuit element;
a clock generator operatively coupled to the first sequential circuit element;
at least a first programmable delay element having an input adapted for receiving at least one of a data signal supplied to the circuit and a clock signal generated by the clock generator, and having an output coupled to at least one of a data input and a clock input of the first sequential circuit element, the first programmable delay element having a first delay associated therewith which is selectively controllable as a function of a first control signal; and
at least one processor connected in a feedback configuration with the at least first sequential circuit element, the processor being operative to receive the clock signal and an output signal of the first sequential circuit element and to generate the first control signal as a function of the clock signal and at least one measured timing parameter of the circuit, the processor being further operative to control a timing of the data signal supplied to the circuit.
